(19) United States
(12) Patent Application Publication
(10) Pub. No.: US 2025/0283936 A1
(43) Pub. Date: Sep. 11, 2025

(54) SOCKET RANKING METHOD FOR SEMICONDUCTOR TEST APPARATUS AND SEMICONDUCTOR TEST METHOD USING THE SOCKET RANKING METHOD

(71) Applicant: Samsung Electronics Co., Ltd., Suwon-si (KR)

(72) Inventors: Taekyung KO, Suwon-si (KR); Chulmin LEE, Suwon-si (KR); Hanseung KWON, Suwon-si (KR); Heejeong KWON, Suwon-si (KR)

(73) Assignee: Samsung Electronics Co., Ltd., Suwon-si (KR)

(21) Appl. No.: 18/932,987

(22) Filed: Oct. 31, 2024

(30) Foreign Application Priority Data
Mar. 5, 2024 (KR) 10-2024-0031526

(51) Int. Cl. G01R 31/28

(52) U.S. Cl. CPC G01R 31/2863; G01R 31/2867

(57) ABSTRACT

Provided are socket ranking methods for a semiconductor test apparatus including a plurality of sockets and a storage device, and configured to load semiconductor chips into respective sockets and perform tests. The socket ranking method include assigning priority to each of the sockets based on a point calculated for each of the sockets and storing the assigned priority in the storage device.

### CROSS-REFERENCE TO RELATED APPLICATION

This application is based on and claims ranking under 35 U.S.C. § 119 to Korean Patent Application No. 10-2024-0031526, filed on Mar. 5, 2024 in the Korean Intellectual Property office, the disclosure of which is incorporated by reference herein in its entirety.

### BACKGROUND

The inventive concepts relate to socket ranking methods for a semiconductor test apparatus and semiconductor test methods, and in particular, to socket ranking methods for a semiconductor test apparatus that may improve the speed of the semiconductor test process, save power, and improve the yield of semiconductor chips, and semiconductor test methods.

The semiconductor test process among the semiconductor manufacturing processes is a process to determine whether semiconductor chips are normal or defective, and determine whether the semiconductor chips are normal or defective by using a signal output in response to a transmitted electrical signal, after power and the electrical signal are transmitted to the semiconductor chips.

Recently, the types of semiconductor devices are diversified according to the trend of high speed, high performance, and high integration of the semiconductor devices, and in response to this trend, test apparatuses testing the semiconductor chips are also in a trend of high speed and high performance.

### SUMMARY

Some example embodiments of the inventive concepts provide socket ranking methods of a semiconductor test apparatus capable of increasing the yield of a semiconductor chip test and semiconductor test methods using the socket ranking method.

Some example embodiments of the inventive concepts provide socket ranking methods of a semiconductor test apparatus capable of improving the test speed of the semiconductor chip test and semiconductor test methods using the socket ranking method.

Some example embodiments of the inventive concepts provide socket ranking methods of a semiconductor test apparatus capable of reducing power used for the semiconductor chip test and semiconductor test methods using the socket ranking method.

The issues to be solved by the technical idea of the inventive concepts are not limited to those mentioned above, and other issues may be clearly understood by those of ordinary skill in the art from the following descriptions.

According to an example embodiment, a socket ranking method for a semiconductor test apparatus, the semiconductor test apparatus comprising a plurality of sockets and a storage device, and configured to load semiconductor chips into respective sockets, respectively, and perform tests thereon, may be provided. The socket ranking method may include loading the semiconductor chips into the sockets, and performing a primary determination for the loaded semiconductor chips as one of Pass or Fail based on first criteria, reloading the semiconductor chips determined as Fail based on a result of the primary determination into the sockets, performing a secondary determination for the semiconductor chips reloaded into the sockets, as one of Pass or Fail based on second criteria, calculating a point of each of the sockets and storing the point in a storage device, by adding or deducting the point for each of the sockets, based on the result of the primary determination and a result of the secondary determination, and assigning priority to each of the sockets based on the point calculated therefor and storing the assigned priority in the storage device.

According to an example embodiment, a socket ranking method for a semiconductor test apparatus, the semiconductor test apparatus comprising a plurality of sockets and a storage device, and configured to load semiconductor chips into sockets, respectively, and perform tests thereon, may be provided. The socket ranking method may include loading the semiconductor chips into the sockets, and performing a primary assignment of one or more types of first indicators to the loaded semiconductor chips, reloading the semiconductor chips into some of the sockets based on the first indicators assigned to semiconductor chips, performing a secondary assignment of one or more types of second indicators to the reloaded semiconductor chips based on a criterion, adding or deducting a point to each of the sockets based on the first indicators assigned to the semiconductor chips at the primary assignment and the second indicators assigned to the semiconductor chips at the secondary assignment, calculating the point for each of the sockets, and storing the calculated point in the storage device, and assigning priority to each of the sockets based on the point calculated therefor and storing the assigned priority in the storage device.

According to an example embodiment, a semiconductor test method for a semiconductor test apparatus, the semiconductor test apparatus comprising a plurality of sockets and a storage device, and configured to load semiconductor chips into sockets, respectively, and perform tests thereon, may be provide. The semiconductor test method may include loading the semiconductor chips into the sockets, performing repeatedly tests on the loaded semiconductor chips, calculating a point for each of the sockets according to first criteria, and storing the point in the storage device, assigning priority to each of the sockets based on the point for each of the sockets stored in the storage device, and storing the assigned priority to each of the sockets in the storage device, selecting a group of sockets to be used for tests based on the priority to each of the sockets stored in the storage device, and loading the semiconductor chips into the selected group of the sockets based on the priority to each of the sockets, and performing the tests.

### BRIEF DESCRIPTION OF THE DRAWINGS

Example embodiments will be more clearly understood from the following detailed description taken in conjunction with the accompanying drawings in which:

FIG. 1 is a block diagram for explaining an operation of a semiconductor test apparatus, according to an example embodiment;

FIG. 2 is a schematic flowchart of a socket ranking method of a semiconductor test apparatus, according to an example embodiment;

FIGS. 3A and 3B are detailed diagrams of a socket ranking method of a semiconductor test apparatus according to an example embodiment;

FIG. 4 is a schematic flowchart of a socket ranking method of a semiconductor test apparatus, according to another example embodiment;

FIG. 5 is a detailed table of a socket ranking method of a semiconductor test apparatus, according to an example embodiment; and

FIG. 6 is a flowchart of a test method of a semiconductor test apparatus, according to an example embodiment.

### DETAILED DESCRIPTION

Hereinafter, some example embodiments of the inventive concepts are described in detail with reference to accompanying diagrams. When it is described in the following descriptions that one component is connected to another component, the one component may be directly connected to the another component, but a third component may also be arranged therebetween. In addition, a structure or size of each component in the drawing is exaggerated for convenience and clarity of descriptions, and portions of each component unrelated to the descriptions are omitted. On the other hand, the terms used herein are used only for the purpose of describing the inventive concepts, and are not used to limit the meaning or to limit the scope of the inventive concepts described in the claims. Identical reference numerals are used for the same constituent elements in the drawings, and duplicate descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

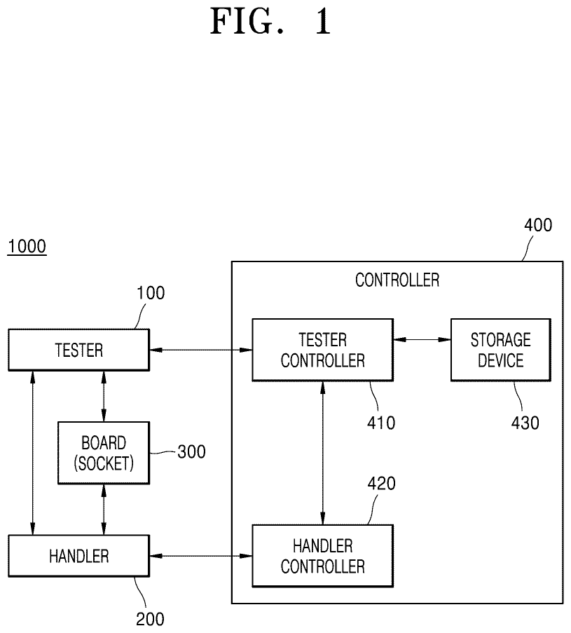

FIG. 1 is a block diagram of an operation of a semiconductor test apparatus 1000, according to an example embodiment.

In this example embodiment, the semiconductor test apparatus 1000 may include, for testing, a tester 100, a handler 200, a board 300, and a controller 400.

In the example embodiments of the inventive concepts, a semiconductor chip may include all semiconductor products including circuits. The semiconductor chip may include a semiconductor device to be tested together with a circuit, for example, a storage device, such as NAND flash and dynamic random access memory (DRAM), but is not limited thereto.

A component for performing a test of the semiconductor chip may be referred to as the tester 100, and a component for performing loading and unloading of the semiconductor chip may be referred to as the handler 200. The tester 100 may include hardware and/or software required to electrically inspect the semiconductor chip.

The tester 100 may electrically test the semiconductor chip. In this case, the test may mean an electrical inspection. For example, the electrical inspection may include whether a circuit is open or short, or the like, but is not limited thereto. The tester 100 may include a processor (not illustrated) controlling the tester 100.

The handler 200 may include a component for loading or unloading semiconductor chips on or from the board 300 to be described below, for testing. The handler 200 may be controlled separately from the tester 100. The handler 200 may include a kind of robot. The handler 200 may include a loader (not illustrated) for loading a test target semiconductor chip onto the board 300 and an unloader (not illustrated) for unloading the test-completed semiconductor chip from the board 300. The handler 200 may be electrically connected to the tester 100 to transceive signals to and from the tester 100.

A plurality of sockets may be arranged on the board 300. The board 300 may include a component in which a plurality of sockets are mounted on a kind of printed circuit board.

A semiconductor chip may be loaded in each of the sockets. The semiconductor test apparatus 1000 may load the semiconductor chips into the sockets of the board 300 by using the handler 200, and may perform a test on the semiconductor chips loaded into the sockets by using the tester 100.

A plurality of semiconductor chips may be loaded into the sockets of the board 300 of the semiconductor test apparatus 1000. For example, about 64 to about 1024 sockets may be arranged on the board 300, and the semiconductor chips corresponding to the number of sockets may be loaded. However, the number of semiconductor chips which are loaded on the board 300 is not limited thereto, and the number of sockets arranged on the board 300 may be freely changed as desired.

The semiconductor test apparatus 1000 described in the present example embodiment may simultaneously test a plurality of semiconductor chips loaded in the plurality of sockets. Accordingly, the semiconductor test apparatus 1000 may simultaneously test in parallel a plurality of semiconductor chips loaded on one board 300, and by repeating this process, may quickly test a large number of semiconductor chips.

The test of the semiconductor chip performed by the semiconductor test apparatus 1000 may mean loading the semiconductor chips into the sockets of the board 300 by using the handler 200 and determining (e.g., testing) the loaded semiconductor chips as either good products or defective products. Determination of the semiconductor chips may be performed by the tester 100. The result of the test may be divided into either a good product or a defective product, and stored in a storage device 430.

The controller 400 may include a tester controller 410, a handler controller 420, and the storage device 430.

The controller 400 may include a processor, etc. The tester controller 410 may be electrically connected to the storage device 430 to control input/output of data to/from the storage device 430.

The tester controller 410 may include a component for separately controlling the tester 100, and the handler controller 420 may include a component for separately controlling the handler 200. The tester controller 410 and the handler controller 420 may be electrically connected to each other to exchange electrical signals.

The storage device 430 may include a memory device, such as NAND flash and/or DRAM.

The controller 400 may include a server connected to the tester 100 in a network. When the controller 400 includes a server, the tester controller 410 and the handler controller 420 may also include separate servers, and the storage device 430 may include a separate database connected to the tester controller 410 in a network. In this case, the tester controller 410, the handler controller 420, and the storage device 430 may be independent components, and may be connected to each other in a network.

When the controller 400 includes a server, one controller 400 may be connected to several testers 100 and several handlers 200 to control them. However, for convenience, FIG. 1 illustrates that the tester 100 and the handler 200 each are a single component.

On the other hand, the lifespan of the sockets arranged on the board 300 is not permanent, and prone to be defective. A defect of the socket may be distinguished from the defect of the semiconductor chip to be tested. When a defect in the socket occurs, the accuracy of the test on the semiconductor chip may be reduced, and a retest may be desired to address deteriorated efficiency of the test process of the semiconductor chip. For example, when a defect occurs in the socket, the semiconductor chip, which needs to be determined as Pass, may be misjudged as Fail. When this issue is not attended to, the yield of semiconductor chips may be lower than the yield actually is, and the semiconductor chips, which are good products, may not be properly utilized. Accordingly, quickly and accurately determining whether sockets for testing semiconductor chips are defective may be an important task in the semiconductor test process.

According to some example embodiments of the inventive concepts, it may be possible to more efficiently determine whether a socket of a semiconductor test apparatus for testing a semiconductor chip is defective and improve the efficiency of the test process.

Descriptions above may also be applied to components mentioned in the description of the following example embodiments below.

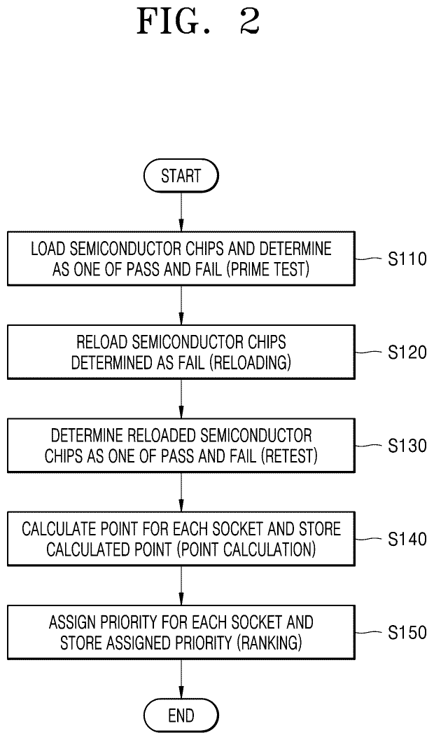

FIG. 2 is a schematic flowchart of a socket ranking method of the semiconductor test apparatus 1000, according to an example embodiment.

As described above with reference to FIG. 1, the semiconductor test apparatus 1000 of the present example embodiment may include the tester 100, the handler 200, the board 300, the controller 400, etc., and the controller 400 may include the tester controller 410 and the handler controller 420.

The handler controller may control the handler to load the semiconductor chips into the sockets on the board. Thereafter, the tester controller may control the tester to perform a prime test operation of determining the loaded semiconductor chips as either Pass or Fail according to desired or pre-defined criteria that has been individually set (S110).

The controller may further include a storage device, the result of the test of each of the semiconductor chips, which has been performed by the tester may be transmitted to the tester controller, and the tester controller may divide the result of the test into either Pass or Fail and store them in the storage device.

When the prime test on the plurality of semiconductor chips loaded into the sockets is completed, the handler controller may control the handler and unload the semiconductor chips from the sockets of the board. The semiconductor chips unloaded may be physically separated from the sockets of the board.

After the prime test is completed, the tester controller may transmit a list of semiconductor chips, which have been determined as Fail, to the handler controller. A unique number (hereinafter, referred to as a ‘chip code’) may be assigned to each of the semiconductor chips. By using the chip code, the tester controller and the handler controller may exchange a list of semiconductor chips which have been determined as either Pass or Fail.

The handler controller may perform a reloading operation of loading again the semiconductor chips determined as Fail into the sockets in the prime test operation by controlling the handler (S120). Accordingly, the semiconductor chips, which are reloading targets in the reloading operation, may include the semiconductor chips which have been determined as Fail in the prime test operation.

Each of the test target semiconductor chips in the reloading operation may be reloaded by the handler into the sockets except for the sockets into which the corresponding semiconductor chip has been loaded.

For example, the sockets, into which the semiconductor chips are loaded again in the reloading operation, may include the remaining sockets except for the sockets into which the semiconductor chips determined as Fail in the prime test operation have been loaded.

As another example, the sockets, into which the semiconductor chips are reloaded in the reloading operation, may include the sockets into which the semiconductor chips determined as Pass in the prime test operation have been loaded.

In other words, each of the reloading target semiconductor chips may not be reloaded into the same socket as the socket into which the corresponding semiconductor chip has been loaded in the prime test. This is because loading the same semiconductor chip into the same socket twice may lose the meaning of the retest subsequent to the prime test.

After the reloading operation is completed, the tester controller may control the tester to perform a retest operation of determining the reloaded semiconductor chips as either Pass or Fail according to desired or pre-defined criteria that has been individually set (S130). As with the prime test operation, a determination result of the retest on each of the semiconductor chips may be divided into either Pass or Fail, and stored in the storage device 430. A criterion for determining the semiconductor chips in the prime test operation and a criterion for determining the semiconductor chips in the retest operation may be the same.

Because each of the semiconductor chips reloaded by the handler in the reloading operation may have been loaded into a socket different from the socket, to which each of the semiconductor chips has been loaded in the prime test operation, each of the semiconductor chips, which is a test target in the retest operation, may be re-determined in a socket different from the socket into which the test target has been loaded at the time when the test target has been determined as Fail in the prime test operation.

During the retest operation, the semiconductor chips, which have been determined as Pass, may be reclassified as good products. The retest operation may be performed once or multiple times. However, for convenience of description, in the present example embodiment, descriptions are given on the basis that the retest operation is performed once.

When the retest operation is repeatedly performed, a semiconductor chip, which has been determined as Fail twice or more, may be re-classified as Pass. Thus, as the retest operation is repeated, more semiconductor chips, which have been incorrectly determined as Fail, may be rescued, and the test accuracy and yield of the semiconductor test apparatus may be improved. However, the time and cost needed for the semiconductor chip test operation may increase, accordingly. Thus, it may be desired to improve the accuracy and the yield of the semiconductor test by improving the accuracy of the prime test and/or the retest, and at the same time, it may be desired to reduce the time and cost for the tests.

The accuracy of the prime test and/or the retest may be dependent on accurately identifying whether sockets arranged on a board of a semiconductor test apparatus are defective, and testing the semiconductor chips by using the sockets which are not defective.

Thus, by accurately identifying the defective sockets of the semiconductor test apparatus, the time and cost desired for the semiconductor chip test may be reduced, and the yield of the semiconductor chip test as well as the test speed may also be improved.

After the retest operation is completed, the semiconductor test apparatus may perform a point calculation operation of calculating a point of each socket and storing the calculated point in the storage device, by adding or subtracting a point for each socket according to desired or pre-defined criteria, based on a determination result for the semiconductor chips in the prime test operation and a determination result for the semiconductor chips in the retest operation (S140). Calculation and storage of points for the sockets may be controlled by the tester controller.

A unique number (hereinafter, socket number) may be assigned to each socket. A point may be calculated and assigned for each socket number.

For example, a semiconductor chip determined as Fail in the prime test operation may be determined as Pass in the retest operation. In this case, because the socket, into which a semiconductor chip, a good product, has been loaded in the prime test operation, is misjudged as defective, the reliability of the test may have decreased.

To the contrary, a semiconductor chip determined as Fail in the prime test operation may still be determined as Fail in the retest operation also. In this case, it may be regarded that the reliability of the socket loaded in the prime test operation and the socket loaded in the retest operation has no issue or is improved.

The deduction/addition point criteria for the socket presented in the present example embodiment may be only one example, and other criteria for determining reliability of one socket may be applicable to the deduction/addition point criteria for another socket, some example embodiment of which may also be included in the protection scope of the inventive concepts.

According to the determination criteria described above, the points may be deducted for sockets with reduced reliability, and the points may be added for sockets with no issue in reliability or with improved reliability.

On the other hand, to calculate the points for the sockets as described above, it may be desired to trace the sockets into which the plurality of semiconductor chips have loaded, respectively. In some example embodiments of the inventive concepts, the tracing may mean storing and memorizing sockets where the semiconductor chips have been tested, respectively. For example, a unique identification code (hereinafter, referred to as a ‘chip code’) may be assigned to each of the test target semiconductor chips. In this case, for each chip code, the unique socket number of a socket in which determination of a semiconductor chip is performed in the prime test operation and the unique socket number of a socket in which determination of a semiconductor chip is performed in the retest operation may be stored in the storage device. In this manner, the list of sockets in which semiconductor chips have been tested may be identified. The meaning of tracing for the sockets may be used in the same manner throughout the specification.

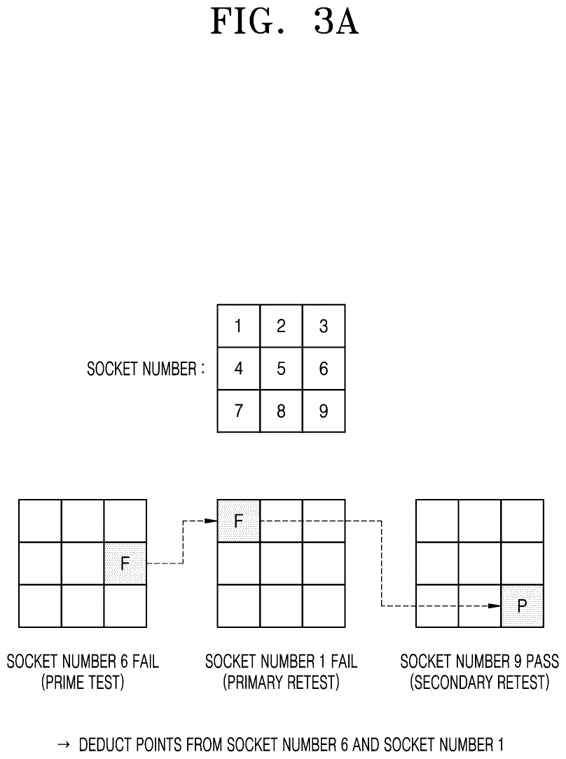

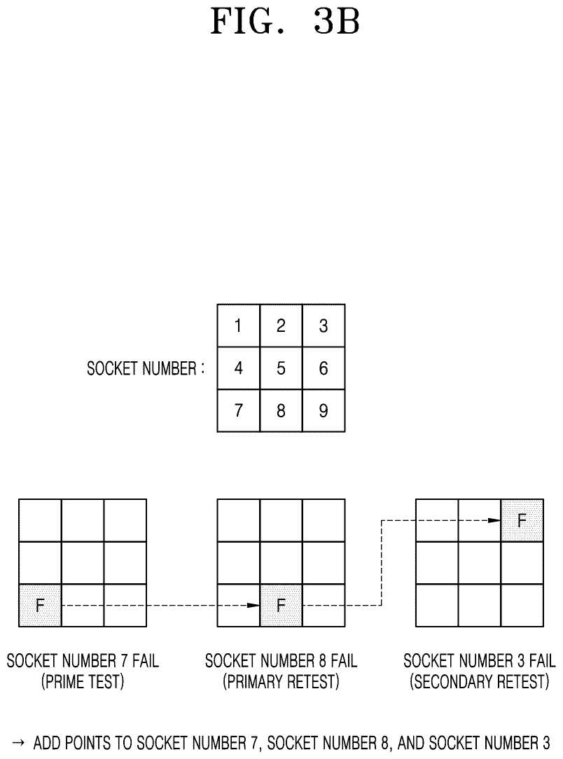

By using the socket number and chip code, the sockets, into which respective semiconductor chips have been loaded in the prime test operation and the sockets, into which respective semiconductor chips have been loaded in the retest operation, may be traced, and a deduction or addition of points may be performed accordingly. This issue is described in more detail with reference to FIGS. 3A and 3B.

After the point calculation operation is completed, a ranking operation of assigning priority to each socket based on the point calculated for each socket and storing the priorities in the storage device may be performed (S150). The ranking operation of the sockets may be performed by the tester controller.

The prime test operation S110, the reloading operation S120, the retest operation S130, the point calculation operation S140, and the ranking operation S150 may be repeated as a procedure forming a set for ranking the sockets.

In the point calculation operation (S140), the semiconductor test apparatus may repeatedly perform tests on the semiconductor chips, accumulate points for each of the calculated sockets, and store the points in the storage device.

The ranking operation on the sockets may be performed based on the points calculated for each socket in the point calculation operations that have been repeated several times.

For example, the tester controller may assign the priority to each socket based on the points stored in the storage device by accumulating the points for each socket in the point calculation operation, and store data on the priorities in the storage device.

In some example embodiments of the inventive concepts, the deduction and addition operations of the points for a socket may have a relative meaning based on the ranking operation. For example, when points are added to the points of the sockets of Group A, but the points of the sockets of Group B different from Group A are not changed, Group B may be considered as relatively deducted. As another example, when points are deducted from the points of the sockets of Group A, but the points of the sockets of Group B are not changed, Group B may be considered as relatively added. As another example, when points are added to the points of the sockets of Group A, but points are deducted from the points of the sockets of Group B, Group B may be considered as relatively deducted. Thus, in some example embodiments of the inventive concepts, adding points to particular sockets may mean giving points so that the ranking of the particular sockets is higher than the ranking of other sockets, and deducting points from particular sockets may mean taking off points so that the ranking of the particular sockets is lower than the ranking of other sockets.

The method of addition and deduction described above may be only an example, and the addition and deduction may also be performed in a method different from the method described above based on the ranking of sockets.

FIGS. 3A and 3B are detailed diagrams of a socket ranking method of the semiconductor test apparatus 1000, according to an example embodiment.

Hereinafter, in the socket ranking method of the semiconductor test apparatus described above with reference to FIG. 2, more detailed descriptions of the point calculation operation S140 performed after the prime test operation S110, the reloading operation S120, and the retest operation S130 are given with reference to FIGS. 3A and 3B.

In the point calculation operation S140, a point for each socket may be calculated by adding or deducting points according to a desired or pre-defined criterion for each socket, and the calculated point may be stored in the storage device.

A socket number may be assigned to each socket. A plurality of sockets may be arranged on one board. For example, about 64 to about 1024 sockets may be arranged on a board, but there is no particular limit to the number of sockets to be arranged on the board and the number of sockets may be freely changed as desired.

The number of semiconductor chips corresponding to the number of sockets may be loaded on the board. The number of semiconductor chips to be loaded on the board is not limited to the numerical range described above, and may be freely changed as desired.

However, for convenience and understanding of the description, in the embodiments described with reference to FIGS. 3A and 3B, descriptions may be simplified such that there are nine sockets and the socket numbers are assigned with numbers ranging from 1 to 9.

Referring to FIGS. 3A and 3B, nine sockets may be assigned with socket numbers of 1, 2, 3, 4, 5, 6, 7, 8, and 9, respectively. Socket numbers are different for each socket, and socket numbers may not be duplicated.

Firstly, the point calculation operation may be described with reference to FIG. 3A. For convenience of descriptions, descriptions are given assuming that the prime test and the retest are performed on one semiconductor chip. Although FIG. 3A illustrates that the retest is performed twice following the prime test, the number of retests may be performed more than once and may have no limit thereto.

Referring to FIG. 3A, in the prime test operation, the target semiconductor chip may have been loaded into the socket number 6 and determined as Fail. In the subsequent first retest, the target semiconductor chip may be loaded into socket number 1 and determined as Fail again. In the subsequent second retest, the target semiconductor chip may be loaded into socket number 9 and determined as Pass here. The order of the sockets loaded in the order of 6, 1, and 9 may be arbitrary.

The sockets, into which the semiconductor chips are loaded again in the retest operation, may include the remaining sockets except for the sockets into which the semiconductor chips determined as Fail in the prime test operation have been loaded. Because the target semiconductor chip, which is retested in the retest operation, has been loaded into other sockets (socket number 1 and socket number 9) rather than the socket (socket number 6), into which the target semiconductor chip has been loaded in the prime test operation, the target semiconductor chip may be loaded into new sockets regardless of a failure in the socket, into which the target semiconductor chip has been loaded in the prime test operation, and may be determined again.

In the example embodiment illustrated in FIG. 3A, the test target semiconductor chip may be loaded into different three sockets (number 6, 1, and 9) from each other, and although the test target semiconductor chip may have been determined as Fail in the socket number 6 and the socket number 1, the test target semiconductor chip may be determined as Pass in the socket number 9.

In this case, because it is possible to conclude that the semiconductor chip, which ought to be determined as Pass in the socket number 6 and the socket number 1, has been determined as Fail, reliability of the socket number 6 and the socket number 1 may be reduced, and may be targets for deducting points therefrom.

On the other hand, because it is possible to conclude that the socket number 9 has no particular issue and is considered as a socket, for which mis-determination is correctable and thus may have improved reliability, the socket number 9 may be a target for adding points thereto.

According to the example embodiment illustrated in FIG. 3A, in the point calculation operation, when the test target semiconductor chip is determined as Pass in the retest operation, by tracing and selecting the sockets, into which the test target semiconductor chip has been loaded and determined as Fail before, and deducting the points therefrom, and by tracing and selecting the sockets, into which the test target semiconductor chip has been loaded and determined as Pass, and adding the points thereto, the points for the sockets may be calculated.

In this manner, the prime test operation, the retest operation, and the point calculation operation may be performed on the plurality of sockets and the plurality of semiconductor chips. For example, when the retest operation is performed once, by tracing and selecting the sockets, into which the semiconductor chips have been loaded and determined as Pass, and adding points thereto, the points of the sockets may be calculated.

To this end, the sockets, into which the semiconductor chips have been loaded, respectively, in the prime test operation, may be traced.

Next, the point calculation operation is described illustrated in FIG. 3B. For convenience of descriptions, descriptions are given assuming that the prime test and the retest are performed on one semiconductor chip. Although FIG. 3B illustrates that the retest is performed twice following the prime test, the number of retests may be performed more than twice and may have no limit thereto.

Referring to FIG. 3B, in the prime test operation, the target semiconductor chip may have been loaded into the socket number 7 and determined as Fail. In the subsequent first retest, the target semiconductor chip may be loaded into socket number 8 and determined as Fail again. In the subsequent second retest, the target semiconductor chip may be loaded into socket number 3 and determined as Fail here. The order of the sockets loaded in the order of 7, 8, and 3 may be arbitrary.

The sockets, into which the semiconductor chips are loaded again in the retest operation, may include the remaining sockets except for the sockets into which the semiconductor chips determined as Fail in the prime test operation have been loaded. Because the target semiconductor chip, which is retested in the retest operation, has been loaded into other sockets (socket number 8 and socket number 3) rather than the socket (socket number 7), into which the target semiconductor chip has been loaded in the prime test operation, the target semiconductor chip may be loaded into new sockets regardless of a failure in the socket, into which the target semiconductor chip has been loaded in the prime test operation, and may be determined again.

In the example embodiment illustrated in FIG. 3B, the target semiconductor chip may be loaded into three different sockets (7, 8, and 3), and may be determined as Fail in all three different sockets. In this case, because it is possible to conclude that all three sockets have no particular issue, there may be no particular issue in the test reliability, and accordingly, all three sockets may be targets for adding points.

According to the example embodiment illustrated in FIG. 3B, in the point calculation operation, when the test target semiconductor chip is determined as Fail in the retest operation, by tracing and selecting the sockets, into which the test target semiconductor chip has been loaded and determined as Fail before, and deducting the points therefrom, and adding the points thereto, the points for the sockets may be calculated.

In this manner, the prime test operation, the retest operation, and the point calculation operation may be performed on the plurality of sockets and the plurality of semiconductor chips. For example, when the retest operation is performed once, by tracing and selecting the sockets, into which the semiconductor chips have been loaded and determined as Fail, and the sockets, into which the semiconductor chips have been loaded again in the retest operation, and deducting points therefrom, the points of the sockets may be calculated by addition points.

To this end, the sockets, into which the semiconductor chips have been loaded in the prime test operation, respectively, may be traced.

As the calculation of the points is repeated as described above, and the results thereof are accumulated, the sockets may be sequenced according to the reliability thereof. The tester controller may request the handler controller to use the socket of relatively high reliability for the test, and the handler controller may increase the yield and efficiency of the test of the semiconductor chip by controlling the handler as requested, and thus, may save time and cost.

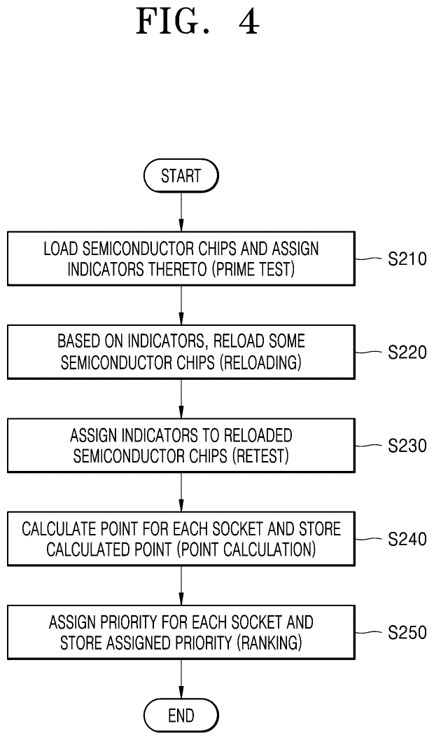

FIG. 4 is a schematic flowchart of a socket ranking method of the semiconductor test apparatus 1000, according to an example embodiment.

To avoid repeated descriptions, duplicate descriptions may be omitted.

As described above with reference to FIG. 1, the semiconductor test apparatus 1000 of the present example embodiment may include the tester 100, the handler 200, the board 300, the controller 400, etc. The controller 400 may include the tester controller 410 and the handler controller 420.

The tester may perform the prime test operation, in which one or more types of indicators are assigned to the loaded semiconductor chips according to a desired or preset criterion (S210). The result of the test for each semiconductor chip may be expressed as one or more types of indicators and stored in the storage device.

In some example embodiments, the indicator may include a numerical value or a code indicating whether an individual semiconductor chip is good or defective.

For example, when the indicator includes one type of a first indicator, the first indicator may be expressed as one of natural numbers ranging from 1 to 8, the semiconductor chips having the first indicators representing 1, 2, 3, or 4 may be determined as good products, and the semiconductor chips having the first indicators representing 5, 6, 7, or 8 may be determined as defective products. In this case, the indicators assigned to the semiconductor chips, which are good products, may be different from each other, and the indicators assigned to the semiconductor chips, which are defective products, may also be different from each other.

In another example, when there are three types of indicators, the indicators may be expressed as the first indicator, a second indicator, a third indicator, respectively. Even in this case, the individual indicators may be expressed in a desired or pre-defined manner, and may indicate whether the semiconductor chips are good products or defective products.

The definition of individual indicators may vary as desired, and the interpretation of the individual indicators may also vary depending on purposes, the application, the type, or the like of the test target semiconductor chip. For example, even when two semiconductor chips present the same indicators, depending on the purpose, use, and type of semiconductor chips, the indicators may mean good products or defective products, and the interpretation of the indicators may change flexibly in operating semiconductor test equipment.

After the prime test operation is completed, the handler may perform the reloading operation of loading some of the semiconductor chips back into the sockets based on the indicators assigned in the prime test operation (S220).

The semiconductor chips loaded again in the reloading operation may include semiconductor chips assigned with the indicators corresponding to a defective product in the prime test operation.

The semiconductor chips to be tested in the reloading operation may be reloaded in the sockets different from the sockets, into which the semiconductor chips have been loaded in the prime test operation.

For example, the sockets, into which the semiconductor chips are reloaded in the reloading operation, may be the sockets other than the sockets, into which the reloading target semiconductor chips have been loaded in the prime test operation. In other words, the reloading target semiconductor chips may not be loaded back into the same sockets as the sockets, into which the reloading target semiconductor chips have been loaded in the prime test operation.

This is because loading the same semiconductor chip into the same socket twice may lose the meaning of the retest operation subsequent to the prime test operation.

After the reloading operation is completed, the tester may perform the retest operation in which one or more indicators are individually assigned to the reloaded semiconductor chips according to a desired or pre-defined criterion (S230). Like the prime test operation, in the retest operation, the determination result of the retest operation for each semiconductor chip also may be given as an indicator and stored in the storage device. A criterion for determining the semiconductor chips in the prime test operation and a criterion for determining the semiconductor chips in the retest operation may be the same.

Because the semiconductor chips reloaded in the reloading operation may have been loaded into a socket different from the socket, to which the semiconductor chips have been loaded in the prime test operation, the semiconductor chips, which include test targets in the retest operation, may be re-assigned with the indicators in the sockets different from the sockets, into which the semiconductor chips have been loaded and determined as defective products in the prime test operation.

The semiconductor chips, which have been assigned with the indicators in the retest operation, may be re-classified as good products. The retest operation may be performed once or multiple times. However, for convenience of description, in the present example embodiment, descriptions are given assuming that the retest operation is performed once.

After the retest operation is completed, the semiconductor test apparatus may perform a point calculation operation of calculating a point of each socket and storing the calculated point in the storage device, by adding or subtracting a point for each socket according to desired or pre-defined criteria, based on an indicator assignment result for the semiconductor chips in the prime test operation and an indicator assignment result for the semiconductor chips in the retest operation (S240). Calculation and storage of points for the sockets may be controlled by the tester controller.

A socket number may be assigned to each socket, and the point may be calculated and assigned to each socket number.

The indicator may be assigned according to various criteria, and descriptions may be given based on an example embodiment, among the example embodiments described above, in which, when the indicator includes one type of the first indicator, the first indicator is expressed as one of natural numbers ranging from 1 to 8, the semiconductor chips having the first indicators representing 1, 2, 3, or 4 is determined as good products, and the semiconductor chips having the first indicators representing 5, 6, 7, or 8 is determined as defective products.

For example, the semiconductor chip determined as a defective product by receiving the first indicator as ‘8’ in the prime test operation may be assigned with the first indicator as ‘3’ which corresponds to a good product in the retest operation. In this case, it may be understood that because the determination result for the corresponding semiconductor chip has been significantly changed from a defective product to a good product or vice versa, reliability of the sockets used in the two test operations has been greatly reduced.

In another example, the semiconductor chip determined as a defective product by receiving the first indicator as ‘8’ in the prime test operation may be assigned with the first indicator as ‘7’ which corresponds to a defective product in the retest operation. In this case, the corresponding semiconductor chip may have been determined as Fail in both the prime test operation and the retest operation, but, because the indicators have been changed, reliability of the two sockets in both the prime test operation and the retest operation may be interpreted as being decreased, but may be interpreted as being less decreased than the case of the example embodiment in which the determination result has been changed from a defective product to a good product or vice versa.

In another example, the semiconductor chip determined as a defective product by receiving the first indicator as ‘8’ in the prime test operation may be assigned with the first indicator as ‘8’ which corresponds to a defective product in the retest operation. In this case, because the corresponding semiconductor chip has been determined as Fail in both the prime test operation and the retest operation, and at the same time, the corresponding indicators are the same, it may be concluded that the two corresponding sockets have no test reliability issue.

In summary, the points may be added/deducted to/from the sockets based on the identicalness of the indicators assigned in the prime test operation and the indicators assigned in the retest operation, and the types of deduction and addition may vary according to the level of reliability.

The deduction/addition point criteria for the socket presented in the present example embodiment may be only one example, and other criteria for determining reliability of one socket may be applicable to the deduction/addition point criteria for another socket, which may also be included in the protection scope of the inventive concepts.

According to the determination criteria described above, the points may be deducted for sockets with reduced reliability, and the points may be added for sockets with no issue in reliability or with improved reliability.

On the other hand, to calculate the points for the sockets as described above, it may be desired to trace the sockets into which the plurality of semiconductor chips have loaded, respectively. For example, a unique chip code may be assigned to each of the test target semiconductor chips. For each chip code, the unique socket number determined at the prime test operation and the unique socket number determined at the retest operation may be stored in the storage device.

By using the socket number and chip code, the sockets, into which respective semiconductor chips have been loaded in the prime test operation and the sockets, into which respective semiconductor chips have been tested in the retest operation, may be traced, and a deduction or addition of points may be performed accordingly.

After the point calculation operation is completed, a ranking operation of assigning priority to each socket based on the point calculated for each socket and storing the priorities in the storage device may be performed (S250). The ranking operation of the sockets may be performed by the tester controller.

The prime test operation S210, the reloading operation S220, the retest operation S230, the point calculation operation S240, and the ranking operation S250 may be repeated as a procedure forming a set for ranking the sockets.

In the point calculation operation, the semiconductor test apparatus may repeatedly perform tests on the semiconductor chips, accumulate points for each of the calculated sockets, and store the points in the storage device.

The ranking operation on the sockets may be performed based on the points calculated for each socket in the point calculation operations that have been repeated several times.

For example, the tester controller may assign the priority to each socket based on the points stored in the storage device by accumulating the points for each socket in the point calculation operation, and store data on the priorities in the storage device.

According to the example embodiment illustrated in FIG. 4, the points of the sockets may be calculated based on whether the indicators assigned to each socket in the semiconductor chip tests performed two or more times are identical. Accordingly, even a socket assigned with an accurate indicator for a semiconductor chip assigned with an inaccurate indicator in the prime test may be inevitably subject to the point deduction. However, as the semiconductor test apparatus repeatedly performs tests on the semiconductor chips and as the points for the sockets are continuously accumulated, the point deduction is accumulated for the sockets assigned with inaccurate indicators, and the point addition is accumulated for the sockets assigned with accurate indicators. Thus, the ranking of sockets may be more meaningful according to repetition of semiconductor tests.

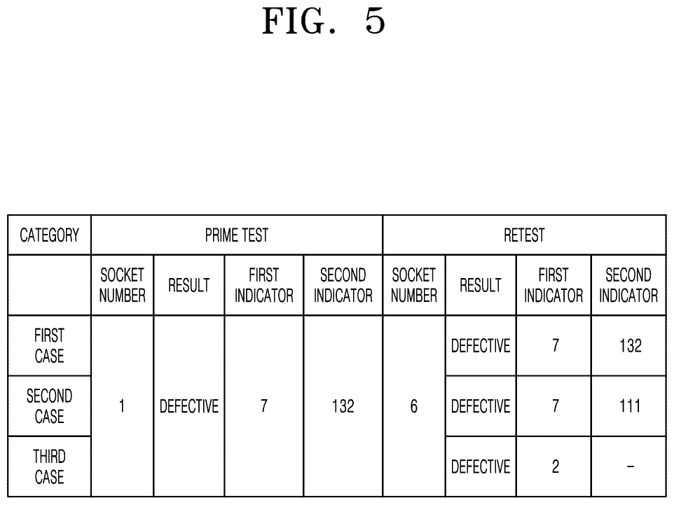

FIG. 5 is a detailed table of a socket ranking method of a semiconductor test apparatus, according to an example embodiment.

In the present example embodiment, descriptions may be given on the premise that the prime test and the retest have been performed one time for one semiconductor chip, there are two types of indicators (the first indicator and the second indicator), and the present example embodiment is divided into three cases (a first case, a second case, and a third case) according to the indicators.

According to the present example embodiment, the first indicator may be assigned with one of ‘1, 2, 3, 4, 5, 6, 7, and 8’, wherein ‘1 to 4’ represent good products and ‘5 to 8’ represent defective products. The second indicator may be assigned only when the first indicator represents a defective product, and the second indicator may be assigned in three digits. In addition, the prime test on the target semiconductor chip may be performed in the socket number 1, and the first indicator may be assigned with ‘7’, which means defective products, and the second indicator may be assigned with ‘132’. Thereafter, the example embodiment may be classified according to the test results in the retest performed in a socket number 6.

In the first case, in the retest operation, the target semiconductor chip may be assigned with ‘7’ indicating a defective product, and the second indicator may be assigned with ‘132’, which are exactly the same as the indicators received in the prime test operation. In this case, because both the socket number 1 and the socket number 6 are assigned with identical indicators for two indicators, both the socket number 1 and the socket number 6 may have high reliability, and thus, the points may be added thereto.

In the second case, in the retest operation, the target semiconductor chip may be assigned with the first indicator as ‘7’ indicating a defective product, but with the second indicator as ‘111’. In this case, the first indicators of the socket number 1 and the socket number 6 may be identical as ‘7’, but the second indicators thereof may be different. Accordingly, the socket number 1 and the socket number 6 in the second case may have lower reliability than the socket number 1 and the socket number 6 in the first case, and may be subject to the point deduction or receive added points that are lower than the points in the first case.

In the third case, the target semiconductor chip may be assigned with the first indicator as ‘2’ indicating a good product, and thus, may not be assigned with the second indicator. In this case, because the indicators of the socket number 1 and the socket number 6 are not the same, and there are large differences in the test result, it may be concluded that the socket number 1 and the socket number 6 in the third case have lower reliability than those in the first case and the second case, and thus, the third case may be a case in which the largest point deduction is applied to the two sockets among the three cases.

According to the example embodiment illustrated in FIG. 4, in the point calculation operation, the indicators assigned to the test target semiconductor chip in the retest operation may be compared with the indicators assigned to the target semiconductor chip in the prime test operation, and based on the comparison result, the point for each socket may be calculated.

For the semiconductor chips for which the indicators determined in the prime test operation and the retest operation are all identical, by selecting the sockets, into which the corresponding semiconductor chips have been loaded in the prime test operation, and the sockets, into which the corresponding semiconductor chips have been reloaded in the retest operation, and adding the points to the sockets, the points of the sockets may be calculated.

On the other hand, for the semiconductor chips for which all or some of the indicators determined in the prime test operation and the retest operation are not identical, by selecting the sockets, into which the corresponding semiconductor chips have been loaded in the prime test operation, and the sockets, into which the corresponding semiconductor chips have been reloaded in the retest operation, and deducting the points to the sockets, the points of the sockets may be calculated. In this case, when all the indicators between the two tests are different, the reliability may be worse than when some of the indicators are different, and thus, larger points may be deducted. In other words, for the semiconductor chips, for which at least some of the indicators are not identical among the indicators determined in the prime test operation and the retest operation, by selecting the sockets, into which the semiconductor chips having relatively more types of indicators that are not identical have been loaded in the prime test operation and the sockets, into which the corresponding semiconductor chips have been reloaded in the retest operation, and by deducting relatively more points, the points of the sockets may be calculated.

In this manner, the prime test operation, the retest operation, and the point calculation operation may be performed on the plurality of sockets and the plurality of semiconductor chips. To this end, the sockets, into which respective semiconductor chips have been loaded in the prime test operation and the sockets, into which the respective semiconductor chips have been reloaded in the retest operation, may be traced.

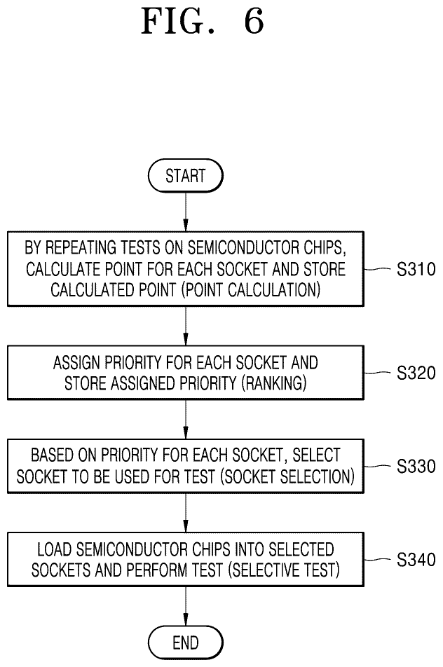

FIG. 6 is a flowchart of a test method of the semiconductor test apparatus 1000, according to an example embodiment.

To avoid repeated descriptions, duplicate descriptions may be omitted.

As described above with reference to FIG. 1, the semiconductor test apparatus 1000 of the present example embodiment may include the tester 100, the handler 200, the board 300, the controller 400, etc. The controller 400 may include the tester controller 410 and the handler controller 420.

The semiconductor test apparatus may perform the point calculation operation (S310), in which the semiconductor chips are loaded into the sockets by controlling the handler, tests on the semiconductor chips, which have been loaded, are repeatedly performed by controlling the tester. The point of each socket may be calculated according to a desired or pre-defined criterion, and the calculated points may be stored in the storage device.

The point calculation operation (S310) described in the present example embodiment as illustrated in FIG. 6 may mean calculating points by repeating the “prime test operation, the reloading operation, the retest operation, and the point calculation operation” as described in the above example embodiments.

Based on the time point of performing the tests on particular semiconductor chips, the “the prime test operation, the reloading operation, the retest operation, and the point calculation operation based on these operations” that have been performed in the past may be regarded as the point calculation operation for the test to be performed at present time point.

In other words, from the standpoint of the semiconductor chip test to be performed at present time, it may be understood that the semiconductor chip tests performed in the past have calculated the points for the sockets to be used for the semiconductor chip test to be performed at present time.

In addition, the semiconductor chip test to be performed at present time may also include a portion of a point calculation process from the standpoint of the semiconductor chip test to be performed in the future.

Thus, the point calculation operation (S310) described in the present example embodiment may mean point calculation by repeating “the prime test operation, the reloading operation, the retest operation, and the point calculation operation” described with reference to FIGS. 2 through 5 for the tests of another semiconductor chip performed in the past.

The method of the point calculation operation (S310) described in the present example embodiment may not be particularly limited, as long as the point is calculated for a socket based on the test result.

In the point calculation operation (S310), the tester controller may accumulate the points of respective sockets, which are calculated by repeatedly performing the tests on the semiconductor chips. In addition, the tester controller may store the accumulated points of the sockets in the storage device. As the semiconductor test apparatus performs the tests on more semiconductor chips, point data of more sockets may be accumulated in the storage device.

On the other hand, in the point calculation operation (S310), as the tests on the semiconductor chips are repeated, the tester controller may apply a weight to the point of each socket calculated in the point calculation operation which has been relatively recently performed. In this manner, a proper evaluation may be secured by evaluating higher the reliability of the test result obtained relatively recently, and by evaluating lower the reliability of the test result obtained relatively in the past.

Furthermore, in the point calculation operation (S310), the tester controller may normalize in a statistical method and accumulate the points of respective sockets that have been calculated by repeatedly performing the test on the semiconductor chips, and may store the accumulated points in the storage device. By normalizing the points of the sockets, although the tests on the semiconductor chips are repeatedly performed, the points of the sockets may be accumulated within a desired or pre-defined number range. Thus, the points of respective sockets may be avoided or prevented from excessively increasing as the tests on the semiconductor chips are repeated, and an analysis of the points may become simple.

According to an example embodiment, a min-max normalization method may be applied. The min-max normalization may convert all data values into a value between about 0 and about 1. For example, the min-max normalization may be expressed by the Formula below.

$${X}^{′} = \frac{X - X min}{X max - X min}$$

In the Formula described above, ‘X’ may mean a calculated point, ‘Xmin’ may mean a minimum point, ‘Xmax’ may mean a maximum point, and ‘X’ may mean a normalized point. Because the points of the sockets after the min-max normalization have values between about 0 and about 1, regardless of deviation in the points, management and analysis of the point data may become simple.

Subsequent to the point calculation operation (S310), the tester controller may perform a ranking operation (S320), in which based on the point calculated per socket, the priority for each socket is assigned and the priority is stored in the storage device.

In the ranking operation, the tester controller may, based on the point stored in the storage device that has been accumulated per socket as the tests on the semiconductor chips have been repeated, assign the priority to each socket, and stored data on the priority in the storage device.

The priorities for the sockets in the ranking operation may be assigned in a descending order of accumulated points.

The ranking operation may be performed each time the point calculation and the point accumulation are completed as the test on the semiconductor chips are repeated. In other words, the ranking operation may be continuously updated.

After the ranking operation is completed, the tester controller may perform a socket selection operation (S330), in which the sockets used for the present tests are selected based on the priorities that have been assigned in the ranking operation. The tester controller may, after the socket selection operation is completed, transmit information about the selected sockets to the handler controller, and request the handler controller to use the selected sockets.

The handler controller may control the handler to load the semiconductor chips into the selected sockets. Next, the tester controller may control the tester to perform a selective test operation (S340) of performing semiconductor tests by using the selected sockets.

For example, when the number of semiconductor chips to be tested at the present time is n, in the socket selection operation, the tester controller may, based on the priorities of the sockets, select the sockets to be used from the sockets of nth priority or greater. Next, in the selective test operation, the handler controller may be requested by the tester controller to use the sockets having the priorities equal to or greater than n, and the handler controller may load n semiconductor chips into the sockets of nth priority or greater to perform the tests. Furthermore, the controller may turn off the sockets of less than nth priority to save power and cost.

In this case, when the number of selected sockets in the socket selection operation is m, it is assumed that n is less than or equal to m.

On the other hand, the number of semiconductor chips to be tested at the present time point may be greater than the number of selected sockets. For example, when the number of semiconductor chips to be tested at the present time point is n, and the number of semiconductor chips selected in the socket selection operation is m, n may be greater than m.

In this case, the controller may, by turning off the sockets of less than m^{th} priority, loading first m semiconductor chips into the sockets of m^{th} or greater priority to test, and loading the remaining (n−m) semiconductor chips after the tests on m semiconductor chips are completed to perform the tests again, may proceed the selective test operation (S340).

By proceeding with the socket selection operation (S330) in this manner, turning off unselected sockets, and then proceeding with the socket selection operation (S330), the sockets having the priorities selected in a reasonable method may be input for the tests first, and thus, the reliability, yield, and efficiency of the tests may be improved, and at the same time, undesirable power consumption may be reduced or prevented by turning off unselected sockets.

Data (indicator or the like) of the sockets, that has been generated by performing the selective test operation (S340), may be utilized in the point calculation operation (S310) and the ranking operation (S320) to be proceeded after the selective test operation (S340), and may be helpful in selecting the sockets having higher reliability in the socket selection operation (S330), in which the sockets to be used for the tests to be proceeded after the point calculation operation (S310) and the ranking operation (S320).

On the other hand, as desired, all or a portion of the accumulated points and priorities of the sockets may need to be deleted from the storage device.

For example, it may be desired to delete the points and priorities of the sockets due to various conditions, such as changes in hardware and/or software of the test target semiconductor chip, changes in the purpose, use, electrical characteristics, or the like of the semiconductor chip, or unreliable existing test data due to aging of devices.

Thus, when a desired or pre-defined condition is satisfied or the semiconductor test apparatus receives a particular input (a user input), the controller may delete the points and priorities of each socket stored in the storage device. In this case, the points and priorities of the sockets may be newly accumulated and stored in a storage device from the semiconductor chip test as to which the deletion has been performed.

The selective test operation (S340) after the socket selection operation (S330) illustrated in FIG. 6 may be more usefully used in the retest operation, but is not limited thereto.

According to the above example embodiments, the controller 400 may turn-off sockets having relatively low priorities on priority and turn-on sockets having the relatively high priories, and thus may enable the semiconductor test apparatus 1000 to test semiconductor chips (e.g., to sort out good and bad semiconductor chips) more quickly and reduce power consumption of the semiconductor test apparatus 1000. In other words, the semiconductor test apparatus 1000 can test semiconductor chips more quickly while consuming less power, thereby improving semiconductor chip testing efficiency and reliability.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various change in form and details may be made therein without departing from the spirit and scope of the following claims.

What is claimed is:

1. A socket ranking method for a semiconductor test apparatus, the semiconductor test apparatus comprising a plurality of sockets and a storage device and configured to load semiconductor chips into sockets, respectively, and perform tests thereon, the socket ranking method comprising:
loading the semiconductor chips into the sockets, and performing a primary determination for the loaded semiconductor chips as one of Pass or Fail based on first criteria;
reloading the semiconductor chips determined as Fail based on a result of the primary determination into the sockets;
performing a secondary determination for the semiconductor chips reloaded into the sockets, as one of Pass or Fail based on second criteria;
calculating a point of each of the sockets and storing the point in the storage device, by adding or deducting the point for each of the sockets, based on the result of the primary determination and a result of the secondary determination; and
assigning priority to each of the sockets based on the point calculated therefor and storing the assigned priority in the storage device.

2. The socket ranking method of claim 1, wherein
the reloading comprises reloading the semiconductor chips into remaining sockets except for the sockets into which the semiconductor chips determined as Fail have been loaded at the primary determination.

3. The socket ranking method of claim 1, wherein
the reloading comprises reloading the semiconductor chips into the sockets into which the semiconductor chips determined as Pass have been loaded at the primary determination.

4. The socket ranking method of claim 1, wherein
the first criteria are identical to the second criteria.

5. The socket ranking method of claim 1, wherein
the calculating comprises
tracing the sockets, into which the semiconductor chips have been loaded at the primary determination, respectively, and the sockets, into which the semiconductor chips have been reloaded at the secondary determination, respectively, and
calculating the point of each of the sockets by
selecting a first group of the sockets, into which the semiconductor chips determined as Fail according to the secondary determination have been loaded at the primary determination, and a second group of the sockets, into which the semiconductor chips have been reloaded at the secondary determination, and
adding the point of each of the sockets to a corresponding one from among the first group of the sockets and the second group of the sockets.

6. The socket ranking method of claim 1, wherein
the calculating comprises,
tracing the sockets, into which the semiconductor chips have been loaded, respectively, at the primary determination, and
calculating the point of each of the sockets by
selecting a first group of the sockets, into which the semiconductor chips determined as Pass at the secondary determination have been loaded at the primary determination, and
deducting the point of each of the socket for a corresponding one from among the first group of the sockets.

7. The socket ranking method of claim 1, wherein
the calculating comprises calculating the point of each of the sockets by
selecting a first group of the sockets, in which the semiconductor chips are determined as Pass have been loaded at the secondary determination, and
adding the point of each of the sockets to a corresponding one from among the first group of the sockets.

8. A socket ranking method for a semiconductor test apparatus, the semiconductor test apparatus comprising a plurality of sockets and a storage device, and configured to load semiconductor chips into sockets, respectively, and perform tests thereon, the socket ranking method comprising:
loading the semiconductor chips into the sockets, and performing a primary assignment of one or more types of first indicators to the loaded semiconductor chips;
reloading the semiconductor chips into some of the sockets based on the first indicators assigned to semiconductor chips;
performing a secondary assignment of one or more types of second indicators to the reloaded semiconductor chips based on a criterion;
adding or deducting a point to each of the sockets based on the first indicators assigned to the semiconductor chips at the primary assignment and the second indicators assigned to the semiconductor chips at the secondary assignment, calculating the point for each of the sockets, and storing the calculated point in the storage device; and
assigning priority to each of the sockets based on the point calculated therefor and storing the assigned priority in the storage device.

9. The socket ranking method of claim 8, wherein
the calculating comprises
tracing the sockets, into which the indicators of each of the semiconductor chips have been loaded at the primary assignment and the sockets, into which the indicators of each of the semiconductor chips have been reloaded at the secondary assignment, and
calculating the point for each of the sockets based on the one or more types of the first indicators and the one or more types of the second indicators.

10. The socket ranking method of claim 9, wherein
the calculating comprises calculating the point for each of the socket, for the semiconductor chips, for which the first indicators assigned at the primary assignment and the second indicators assigned at the secondary assignment are all identical, by
selecting a first group of the sockets, into which corresponding ones of the semiconductor chips assigned with the first indicators at the primary assignment have been loaded, respectively, and a second group of the sockets into which the corresponding ones of the semiconductor chips assigned with the second indicators at the secondary assignment have been loaded, and
adding the point for each of the sockets to a corresponding one from among the first group of the sockets and the second group of the sockets.

11. The socket ranking method of claim 9, wherein
the calculating comprises calculating the point for each of the sockets based on the first indicators assigned to the semiconductor chips at the primary assignment and the second indicators assigned to the semiconductor chips at the secondary assignment, for the semiconductor chips, for which at least some of the indicators assigned at the primary assignment and the indicators assigned at the secondary assignment are not identical, calculating the point for each of the sockets by
selecting a first group of the sockets, into which the corresponding semiconductor chips assigned with the first indicators at the primary assignment are loaded, and a second group of the sockets, into which the corresponding semiconductor chips assigned with the second indicators at the secondary assignment are loaded, and
deducting the point of each of the sockets for a corresponding one from among the first group of the socket and the second group of the sockets.

12. The socket ranking method of claim 11, wherein
the calculating comprises calculating the point for each of the sockets, for the semiconductor chips, for which at least some of the first indicators assigned at the primary assignment and the second indicators assigned at the secondary assignment are not identical, by
selecting a first group of the sockets, into which the semiconductor chips having the first indicators have been loaded at the primary assignment, and a second group of the sockets, into which the semiconductor chips having the second indicators, relatively more type of which are different from the first indicators, have been loaded at the secondary assignment, and
deducting relatively more points for the first group of the sockets and the second group of the sockets.

13. A semiconductor test method for a semiconductor test apparatus, the semiconductor test apparatus comprising a plurality of sockets and a storage device, and configured to load semiconductor chips into sockets, respectively, and perform tests thereon, the semiconductor test method comprising:
loading the semiconductor chips into the sockets, performing repeatedly tests on the loaded semiconductor chips, calculating a point for each of the sockets according to first criteria, and storing the point in the storage device;
assigning priority to each of the sockets based on the point for each of the sockets stored in the storage device, and storing the assigned priority to each of the sockets in the storage device;
selecting a group of sockets to be used for tests based on the priority to each of the sockets stored in the storage device; and
loading the semiconductor chips into the selected group of the sockets based on the priority to each of the sockets, and performing the tests.

14. The semiconductor test method of claim 13, wherein,
the calculating the point for each of the sockets comprises accumulating the point for each of the sockets calculated by repeatedly performing the tests on the loaded semiconductor chips,
the storing point in the storage device comprises storing the accumulated point in the storage device,
the assigning the priority to each of the sockets comprises assigning the priority to each of the sockets based on the point stored in the storage device by accumulating the point for each of the sockets, and
the storing the assigned priority to each of the sockets in the storage device comprises storing the assigned priority to each of the sockets in the storage device.

15. The semiconductor test method of claim 14, wherein,
the calculating the point for each of the sockets comprises, as the tests on the semiconductor chips are repeated, assigning weights to the point for each of the sockets, for each of which the point has been calculated relatively recently based on a reference point in time, and accumulating the assigned weights.

16. The semiconductor test method of claim 13, further comprising:
deleting the point for each of the sockets and the priority for each of the sockets stored in the storage device based on second criteria or an input to the semiconductor test apparatus.

17. The semiconductor test method of claim 14, wherein
the calculating the point for each of the sockets comprises calculating the point for each of the sockets by normalizing and accumulating the point for each of the sockets that have been calculated by repeatedly performing the tests on the semiconductor chips, and
the assigning the priority comprises assigning the priority to each of the sockets based on the accumulated point for each of the sockets.

18. The semiconductor test method of claim 13, wherein,
in a case where a number of semiconductor chips to be tested at a present time point is n,
a first group of the sockets to be used for the tests are selected based on the priority of each of the sockets such that the sockets each having nth or greater priority are selected as the first group of the sockets,
loading the semiconductor chips into the first group of the sockets, respectively,
turning off the sockets each having less than n^{th} priority,
loading the n semiconductor chips into the first group of the sockets, and
performing the tests on the semiconductor chips loaded into the first group of the sockets.

19. The semiconductor test method of claim 13, wherein
in a case where a number of semiconductor chips to be tested at a present time point is n,
the selecting comprises selecting a first group of the sockets to be used for the tests based on the priority of each of the sockets such that a first group of the sockets each having m^{th} or greater priority are selected as the first group of the sockets, and in a case where n is greater than m (n>m),
loading the semiconductor chips into the first group of the sockets, respectively, and performing the tests on the loaded semiconductor chips such that
the sockets each having less than m^{th} priority are turned off,
the m semiconductor chips are first loaded into the sockets each having m^{th} or greater priority, and tested, and
remaining (n−m) semiconductor chips are loaded and tested after completing the tests on the m semiconductor chips.

20. The semiconductor test method of claim 13, wherein
in a case where a number of semiconductor chips to be tested at a present time point is n,
selecting a first group of the sockets to be used for the tests based on the priorities of the sockets such that the sockets each having m^{th} or greater priority are selected as the first group of the sockets, and
in a case where n is less than or equal to m (n≤m),
loading the semiconductor chips are loaded into the first group of the sockets, respectively,
turning off the sockets each having less than n^{th} priority,
loading n semiconductor chips into the sockets each having n^{th} or greater priority, and
performing the tests on the n semiconductor chips.
